(19) United States
(12) Patent Application Publication
(10) Pub. No.: US 2025/0387959 A1
(43) Pub. Date: Dec. 25, 2025

(54) SECURING BOARD IN IN-MOLD ELECTRONICS (IME) PROCESS

(71) Applicant: Covestro LLC, Pittsburgh, PA (US)

(72) Inventors: Joshua D. Wagner, South Park, PA (US); Jessica Gresko, Coraopolis, PA (US); James M. Lorenzo, Mars, PA (US); Jerome F. Hebert, Mason, MI (US)

(21) Appl. No.: 19/241,516

(22) Filed: Jun. 18, 2025

Related U.S. Application Data
(60) Provisional application No. 63/661,932, filed on Jun. 20, 2024.

(30) Foreign Application Priority Data
Jul. 4, 2024 (EP) 24186599.7

(51) Int. Cl. B29C 45/14; B29K 101/12; B29K 105/16; B29K 507/04; B29L 31/34; H05K 3/28

(52) U.S. Cl. CPC B29C 45/14311; H05K 3/284; B29C 2045/14327; B29K 2101/12; B29K 2105/16; B29K 2507/04; B29K 2995/0013; B29L 2031/3425; H05K 2203/1316

(57) ABSTRACT

Provided is a process of securing a board component in an in-mold electronics assembly, the process comprising: inserting the board component into a mold; injecting a thermally conductive thermoplastic polymer composition into the mold and into a flow-through collar to flow over the board component which lies within an insert pocket in the in-mold electronics assembly; cooling the thermally conductive thermoplastic polymer composition securing the board component and forming the in-mold electronics assembly; and removing the in-mold electronics assembly from the mold, wherein the board component optionally includes one or more attachment openings, through holes, through-hole vias, blind vias, buried vias, microvias, stacked microvias, and any combination thereof allowing the thermally conductive thermoplastic polymer composition to flow therethrough.

### FIELD OF THE INVENTION

The present invention relates in general, to electronics, and more specifically, to in-mold electronics and processes for securing LEDs and other boards in electronic assemblies.

### BACKGROUND OF THE INVENTION

State of the art light emitting diode (LED) light bulbs and other electronics contain printed circuit boards and various electronic components which must be electrically isolated from user contact. These devices must also have sufficient thermal management to keep operating temperatures below a critical value to extend the device's service life. However, current high-power LEDs produce a significant heat output as up to 60% of the electric power input is converted into heat.

Another problem inherent with in-mold electronics (IME) processes is that LEDs and printed circuit boards can become detached from the electronic assembly during use resulting in device failure.

To reduce or eliminate problems, therefore, a need exists in the art for a process of securing a board component in an in-mold electronics assembly to reduce the chances of the component becoming detached from the assembly during use. In addition, the proposed solution helps with thermal management.

### SUMMARY OF THE INVENTION

Accordingly, the present invention reduces or eliminates problems inherent in the art by providing a process of securing a board component in an in-mold electronics assembly, the process comprising: inserting the board component into a mold; injecting a thermally conductive thermoplastic polymer composition into the mold and into a flow-through collar to flow over the board component which lies within an insert pocket in the in-mold electronics assembly; cooling the thermally conductive thermoplastic polymer composition securing the board component and forming the in-mold electronics assembly; and removing the in-mold electronics assembly from the mold, wherein the board component optionally includes one or more attachment openings, through holes, through-hole vias, blind vias, buried vias, microvias, stacked microvias, and any combination thereof allowing the thermally conductive thermoplastic polymer composition to flow therethrough. The present invention reduces the chances of the component becoming detached from the assembly during use and assists with thermal management.

These and other advantages and benefits of the present invention will be apparent from the Detailed Description of the Invention herein below.

### BRIEF DESCRIPTION OF THE FIGURES

The present invention will now be described for purposes of illustration and not limitation in conjunction with the figures, wherein:

FIG. 1 is a perspective view of a full in-mold electronics assembly of the invention;

FIG. 2 depicts a perspective view of the part of the in-mold electronics assembly of the invention without the board component;

FIG. 3 illustrates the board component detached from the in-mold electronics assembly of the invention;

FIG. 4 is a close-up view of a portion of FIG. 2 showing tabs and insert anchor for securing the thermoplastic polymer to the insert pocket of the in-mold electronics assembly of the invention; and

FIG. 5 is a photograph showing tabs securing an insert to the in-mold electronics assembly of the invention.

### DETAILED DESCRIPTION OF THE INVENTION

The present invention will now be described for purposes of illustration and not limitation. Except in the operating examples, or where otherwise indicated, all numbers expressing quantities, percentages, and so forth in the specification are to be understood as being modified in all instances by the term “about.”

Any numerical range recited in this specification is intended to include all sub-ranges of the same numerical precision subsumed within the recited range. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited in this specification is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such sub-ranges would comply with the requirements of 35 U.S.C. § 112(a), and 35 U.S.C. § 132(a). The various embodiments disclosed and described in this specification can comprise, consist of, or consist essentially of the features and characteristics as variously described herein.

Any patent, publication, or other disclosure material identified herein is incorporated by reference into this specification in its entirety unless otherwise indicated, but only to the extent that the incorporated material does not conflict with existing definitions, statements, or other disclosure material expressly set forth in this specification. As such, and to the extent necessary, the express disclosure as set forth in this specification supersedes any conflicting material incorporated by reference herein. Any material, or portion thereof, that is said to be incorporated by reference into this specification, but which conflicts with existing definitions, statements, or other disclosure material set forth herein, is only incorporated to the extent that no conflict arises between that incorporated material and the existing disclosure material. Applicant reserves the right to amend this specification to expressly recite any subject matter, or portion thereof, incorporated by reference herein.

Reference throughout this specification to “various non-limiting embodiments,” “certain embodiments,” or the like, means that a particular feature or characteristic may be included in an embodiment. Thus, use of the phrase “in various non-limiting embodiments,” “in certain embodiments,” or the like, in this specification does not necessarily refer to a common embodiment and may refer to different embodiments. Further, the particular features or characteristics may be combined in any suitable manner in one or more embodiments. Thus, the particular features or characteristics illustrated or described in connection with various or certain embodiments may be combined, in whole or in part, with the features or characteristics of one or more other embodiments without limitation. Such modifications and variations are intended to be included within the scope of the present specification.

The grammatical articles “a”, “an”, and “the”, as used herein, are intended to include “at least one” or “one or more”, unless otherwise indicated, even if “at least one” or “one or more” is expressly used in certain instances. Thus, these articles are used in this specification to refer to one or more than one (i.e., to “at least one”) of the grammatical objects of the article. By way of example, and without limitation, “a component” means one or more components, and thus, possibly, more than one component is contemplated and may be employed or used in an implementation of the described embodiments. Further, the use of a singular noun includes the plural, and the use of a plural noun includes the singular, unless the context of the usage requires otherwise.

“Interlocking” as used herein means that a thermally conductive thermoplastic polymer composition at least partially and perhaps fully, enters into a channel, hole, port, bore, or crevice of a component of the assembly. In the case of a printed circuit board, for example, the thermally conductive thermoplastic polymer composition may enter through screw holes, through-holes, and/or vertical interconnect access (via) holes to interlock the electronic/electrical component, such as a printed circuit board, to the in-mold electronics assembly.

“Encapsulate” as used herein means that a thermally conductive thermoplastic polymer composition at least partially and perhaps fully surrounds a component of the in-mold electronics assembly and may flow through the holes in the component. It does not necessarily mean that a component is hermetically sealed against the environment, although it may have such a meaning.

In a first embodiment, the present invention is directed to a process of securing a board component in an in-mold electronics assembly, the process comprising: inserting the board component into a mold; injecting a thermally conductive thermoplastic polymer composition into the mold and into a flow-through collar to flow over the board component which lies within an insert pocket in the in-mold electronics assembly; cooling the thermally conductive thermoplastic polymer composition securing the board component and forming the in-mold electronics assembly; and removing the in-mold electronics assembly from the mold, wherein the board component optionally includes one or more attachment openings, through holes, through-hole vias, blind vias, buried vias, microvias, stacked microvias, and any combination thereof allowing the thermally conductive thermoplastic polymer composition to flow therethrough.

In a second embodiment, the present invention is directed to the process according to the previous paragraph, wherein the board component is further secured with a tab connected to an insert anchor of the in-mold electronics assembly, and wherein the insert anchor contacts the insert pocket through a post.

In a third embodiment, the present invention is directed to a process of securing a board component in an in-mold electronics assembly, the process comprising: inserting the board component into a mold; injecting a thermally conductive thermoplastic polymer composition into the mold and flowing the thermally conductive thermoplastic polymer composition, a) over the board component lying within an insert pocket in the in-mold electronics assembly, forming an insert anchor adjacent to the board component, and b) over a post protruding perpendicularly from the insert pocket, forming a tab; cooling the thermally conductive thermoplastic polymer composition, securing the board component, and forming the in-mold electronics assembly; and removing the in-mold electronics assembly from the mold.

In a fourth embodiment, the present invention is directed to an in-mold electronics assembly comprising: a board component; a flow-through collar; and a thermally conductive thermoplastic polymer composition, wherein the thermally conductive thermoplastic polymer composition is injected into a mold and into the flow-through collar, wherein the thermally conductive thermoplastic polymer composition flows over the board component securing the board component to the in-mold electronics assembly, and wherein the board component optionally includes one or more attachment openings, through holes, through-hole vias, blind vias, buried vias, microvias, stacked microvias, and any combination thereof allowing the thermally conductive thermoplastic polymer composition to flow therethrough.

Because the in-mold electronics assembly of the invention comprises a thermally conductive thermoplastic polymer composition, it functions as a heat sink assisting with thermal management. This effect may be further enhanced by the attachment or molding of a plurality of fins or fin-shaped structures to provide greater surface area to the inventive in-mold electronics assembly.

### Thermally Conductive Polymer

The thermally conductive thermoplastic polymer useful in the present invention may be made from an amorphous thermoplastic polymer or from a blend of an amorphous thermoplastic polymer and a semicrystalline thermoplastic polymer or from a blend of an amorphous thermoplastic polymer and a rubber, such as acrylonitrile-butadiene-styrene (ABS) or styrene-acrylonitrile copolymer (SAN). Such blends are commercially available from Covestro LLC under the BAYBLEND name.

Suitable amorphous thermoplastic polymers within the meaning of this invention are, in particular, amorphous polycarbonates, amorphous polyesters, and amorphous polyolefins as well as, copolymers and polymer blends thereof. Amorphous polyolefins include both open-chain polyolefins such as polypropylene as well as cyclic olefin copolymers. Preferred as amorphous thermoplastic polymers in the context of the present invention are polycarbonate, polymethylmethacrylate (PMMA) and polystyrene, with polycarbonate being particularly preferred.

Amorphous and semicrystalline thermoplastics may be blended into a resin composition useful in the present invention. Examples of blends of amorphous and semicrystalline thermoplastics are well known to those skilled in the art. Some examples of such blends are polycarbonate and polyethylene terephthalate, polycarbonate and polybutylene terephthalate, polycarbonate and polyphenylene sulfide, polycarbonate and), liquid crystalline polymers. Some of these blends are commercially available from Covestro LLC under the name MAKROBLEND. There is no limitation on what kind of amorphous thermoplastic to blend with what kind of semicrystalline thermoplastic provided the resulting blend serves the intended application.

Semicrystalline thermoplastic polymers and methods of their production are known to those skilled in the art. Preferred semicrystalline thermoplastic polymers for use in the inventive composition include, but are not limited to, polyethylene, polypropylene, polybutylene terephthalate and polyethylene terephthalate, polyphenylene sulfide, polyphenylene either, liquid crystalline polymers, or polyamide.

Where present in a blend, the semicrystalline thermoplastic polymer may be present in an amount ranging from 90% to 30% of the composition useful in the present invention, more preferably from 80% to 40% and most preferably from 70% to 50%. The semicrystalline thermoplastic polymer may be present in the composition useful in the present invention in an amount ranging between any combinations of these values, inclusive of the recited values.

The inventive process involves injection molding one of an electronic/electrical component or a metal insert using a thermally conductive thermoplastic polymer composition, preferably a material such as MAKROLON TC8030, a polycarbonate commercially available from Covestro LLC. The board component is inserted into a mold and the thermally conductive thermoplastic polymer composition flows around it to form the in-mold electronic assembly. The board component optionally includes openings, such as attachment holes (e.g., screw holes), through holes, vias, and any combination thereof that allow the thermally conductive thermoplastic polymer composition to pass therethrough and interlock the electronic/electrical component to the in-mold electronic assembly. The mold may include cavities positioned above the openings on the electronic/electrical component or metal insert so that the thermally conductive thermoplastic polymer composition forms caps over the openings.

In certain embodiments of the invention, the holes in the board component may align with the openings in an electric/electronic component so that the thermally conductive thermoplastic polymer composition may pass or flow through the aligned holes/openings and interlock the electric/electronic component and board component to the in-mold electronic assembly. The in-mold electronic assembly may contain features, holes, or undercuts to act as a joint with mechanical interlock to allow connection to a housing, or further reaction injection molded components to better bond to the in-mold electronic assembly.

In some embodiments, the in-mold electronic assembly may be subsequently inserted into a mold designed for reaction injection molded (RIM) of further components. Additional electronics such as an LED driver/controller board may be inserted into a cavity in the in-mold electronic assembly. RIM material, such as polyurethane or another thermoplastic, may be injected into the cavity, filling the lower portion of in-mold electronic assembly encapsulating the additional electronics components.

Thermally conductive polycarbonate is commercially available, for example, from Covestro LLC under the MAKROLON TC8060 and TC8030 names. These materials, which contain polycarbonate and expanded graphite, are particularly preferred in the practice of the present invention and are described in greater detail in U.S. Pat. Pub. No. 2012/0319031. The compositions provided in the '031 application contain from 90 wt. % to 30 wt. % of at least one amorphous thermoplastic or at least one semi crystalline thermoplastic or a mixture thereof and 10 wt. % to 70 wt. % of expanded graphite, wherein 90 wt. % of the particles of the expanded graphite have a particle size of at least 200 microns. As those skilled in the art will appreciate, other thermally conductive polymers may also be used.

Suitable polycarbonate resins for preparing the composition useful in the present invention are homopolycarbonates and copolycarbonates, both linear or branched resins and mixtures thereof. As used herein, the term “polycarbonate” includes homopolycarbonates such as bisphenol A polycarbonate, copolycarbonates derived from two or more different dihydric phenols, and copolyestercarbonates which include structural units derived from one or more dihydric phenols and one or more diacid derived structural units. The diacid, for example, includes dodecanedioic acid, terephthalic acid, isophthalic acid. U.S. Pat. No. 4,983,706 describes a method for making co-polyestercarbonate.

The polycarbonates have a weight average molecular weight (as determined by gel permeation chromatography, or size-exclusion chromatography) of preferably 10,000 to 200,000 g/mol, more preferably 20,000 to 80,000 g/mol and their melt flow rate, per ASTM D-1238 at 300° C. and 1.2 kg weight, is preferably 1 to 80 g/10 min, more preferably 20 to 65 g/10 min. Such polycarbonates may be prepared, for example, by the known diphasic interface process from a carbonic acid derivative such as phosgene and dihydroxy compounds by polycondensation (See, German Offenlegungsschriften 2,063,050; 2,063,052; 1,570,703; 2,211,956; 2,211,957 and 2,248,817; French Patent 1,561,518; and the monograph by H. Schnell, “Chemistry and Physics of Polycarbonates”, Interscience Publishers, New York, N.Y., 1964).

Dihydroxyaryl compounds suitable for the preparation of polycarbonates are those of the formula (1)

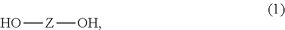

wherein,
Z is an aromatic radical of 6 to 30 carbon atoms which may contain one or more aromatic rings, may be substituted, and may contain aliphatic, cycloaliphatic radicals, alkylaryl groups, or heteroatoms as bridging elements.

Preferably, Z in formula (1) is a radical of the formula (2),

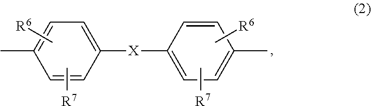

wherein
R⁶ and R⁷ are each independently H, C₁-C₁₈-alkyl-, C₁-C₁₈-alkoxy, halogen such as Cl or Br or in each case optionally substituted aryl or aralkyl, in some embodiments H or C₁-C₁₂-alkyl, in certain embodiments H or C₁-C₈-alkyl and in selected embodiments H or methyl, and
X is a single bond, —SO₂—, —CO—, —O—, —S—, C₁-C₆-alkylene, C₂-C₅-alkylidene or C₅-C₆-cycloalkylidene which may be substituted by C₁-C₆-alkyl, preferably methyl or ethyl, or else C₆-C₁₂-arylene which may optionally be fused to further aromatic rings containing heteroatoms.

In various embodiments, X is a single bond, C₁-C₅-alkylene, C₂-C₅-alkylidene, C₅-C₆-cycloalkylidene, —O—, —SO—, —CO—, —S—, —SO2-or a radical of the formula (2a),

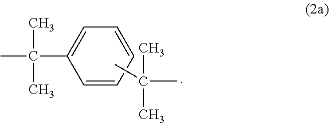

Among the dihydroxy compounds useful in the practice of the present invention are hydroquinone, resorcinol, bis-(hydroxyphenyl)-alkanes, bis-(hydroxy-phenyl)-ethers, bis-(hydroxyphenyl)-ketones, bis-(hydroxy-phenyl)-sulfoxides, bis-(hydroxyphenyl)-sulfides, bis-(hydroxyphenyl)-sulfones, and α,α-bis-(hydroxyphenyl)-diisopropylbenzenes, as well as their nuclear-alkylated compounds. These and further suitable aromatic dihydroxy compounds are described, for example, in U.S. Pat. Nos. 5,401,826; 5,105,004; 5,126,428; 5,109,076; 5,104,723; 5,086,157; 3,028,356; 2,999,835; 3,148,172; 2,991,273; 3,271,367; and 2,999,846.

Further examples of suitable bisphenols are 2,2-bis-(4-hydroxyphenyl)-propane (bisphenol A), 2,4-bis-(4-hydroxyphenyl)-2-methyl-butane, 1,1-bis-(4-hydroxyphenyl)-cyclohexane, α,α-bis-(4-hydroxy-phenyl)-p-diisopropylbenzene, 2,2-bis-(3-methyl-4-hydroxyphenyl)-propane, 2,2-bis-(3-chloro-4-hydroxyphenyl)-propane, 4,4′-dihydroxy-diphenyl, bis-(3,5-dimethyl-4-hydroxyphenyl)-methane, 2,2-bis-(3,5-dimethyl-4-hydroxyphenyl)-propane, bis-(3,5-dimethyl-4-hydroxyphenyl)-sulfide, bis-(3,5-dimethyl-4-hydroxy-phenyl)-sulfoxide, bis-(3,5-dimethyl-4-hydroxyphenyl)-sulfone, dihydroxy-benzophenone, 2,4-bis-(3,5-dimethyl-4-hydroxyphenyl)-cyclohexane, α,α-bis-(3,5-dimethyl-4-hydroxyphenyl)-p-diisopropyl-benzene and 4,4′-sulfonyl diphenol.

Examples of particularly preferred aromatic bisphenols are 2,2-bis-(4-hydroxyphenyl)-propane, 2,2-bis-(3,5-dimethyl-4-hydroxyphenyl)-propane, 1,1-bis-(4-hydroxyphenyl)-cyclohexane and 1,1-bis-(4-hydroxy-phenyl)-3,3,5-trimethylcyclohexane. The most preferred bisphenol is 2,2-bis-(4-hydroxyphenyl)-propane (bisphenol A).

The polycarbonates useful in the invention may entail in their structure units derived from one or more of the suitable bisphenols. Among those resins suitable in the practice of the invention are phenolphthalein-based polycarbonate, copolycarbonates and terpolycarbonates such as are described in U.S. Pat. Nos. 3,036,036 and 4,210,741.

The polycarbonates useful in the present invention may also be branched by condensing therein small quantities, e.g., 0.05 to 2.0 mol % (relative to the bisphenols) of polyhydroxyl compounds. Polycarbonates of this type have been described, for example, in German. Offenlegungsschriften 1,570,533; 2,116,974 and 2,113,374; British Patents 885,442 and 1,079,821 and U.S. Pat. No. 3,544,514. The following are some examples of polyhydroxyl compounds which may be used for this purpose: phloroglucinol; 4,6-dimethyl-2,4,6-tri-(4-hydroxyphenyl)-heptane; 1,3,5-tri-(4-hydroxyphenyl)-benzene; 1,1,1-tri-(4-hydroxyphenyl)-ethane; tri-(4-hydroxyphenyl)-phenyl-methane; 2,2-bis-[4,4-(4,4′-dihydroxydiphenyl)]-cyclohexyl-propane; 2,4-bis-(4-hydroxy-1-isopropylidine)-phenol; 2,6-bis-(2′-dihydroxy-5′-methylbenzyl)-4-methyl-phenol; 2,4-dihydroxybenzoic acid; 2-(4-hydroxy-phenyl)-2-(2,4-dihydroxyphenyl)-propane and 1,4-bis-(4,4′-dihydroxy-triphenylmethyl)-benzene. Some of the other polyfunctional compounds are 2,4-dihydroxy-benzoic acid, trimesic acid, cyanuric chloride and 3,3-bis-(4-hydroxyphenyl)-2-oxo-2,3-dihydroindole.

In addition to the polycondensation process mentioned above, other processes for the preparation of the polycarbonates of the invention are polycondensation in a homogeneous phase and transesterification. The suitable processes are disclosed in U.S. Pat. Nos. 3,028,365; 2,999,846; 3,153,008; and 2,991,273.

The preferred process for the preparation of polycarbonates is the interfacial polycondensation process. Other methods of synthesis in forming the polycarbonates of the invention, such as disclosed in U.S. Pat. No. 3,912,688, may be used. Suitable polycarbonate resins are available in commerce, for instance, from Covestro LLC under the MAKROLON name.

The term polyester as used herein is meant to include homo-polyesters and co-polyesters resins. These are resins, the molecular structure of which include at least one bond derived from a carboxylic acid, preferably excluding linkages derived from carbonic acid. These are known resins and may be prepared through condensation or ester interchange polymerization of the diol component with the diacid according to known methods. Suitable resins include poly (alkylene dicarboxylates), especially poly (ethylene terephthalate) (PET), poly(l,4-butylene terephthalate) (PBT), poly(trimethylene terephthalate) (PTT), poly(ethylene naphthalate) (PEN), poly(butylene naphthalate) (PBN), poly(cyclohexanedimethanol terephthalate) (PCT), poly(cyclohexanedimethanol-co-ethylene terephthalate) (PETG or PCTG), and poly(l,4-cyclohexanedimethyl-1,4-cyclohexanedicarboxylate) (PCCD).

U.S. Pat. Nos. 2,465,319, 3,953,394, and 3,047,539, disclose suitable methods for preparing such resins. The suitable polyalkylene terephthalates are characterized by an intrinsic viscosity of at least 0.2 and preferably at least 0.4 deciliter/gram as measured by the relative viscosity of an 8% solution in orthochlorophenol at 25° C. The upper limit is not critical, but it preferably does not exceed 2.5 deciliters/gram. Especially preferred polyalkylene terephthalates are those with an intrinsic viscosity in the range of 0.4 to 1.3 deciliter/gram.

The alkylene units of the polyalkylene terephthalates which are suitable for use in the present invention contain from 2 to 5, preferably 2 to 4 carbon atoms. Polybutylene terephthalate (prepared from 1,4-butanediol) and polyethylene terephthalate are the preferred tetraphthalates for use in the present invention. Other suitable polyalkylene terephthalates include polypropylene terephthalate, polyisobutylene terephthalate, polypentyl terephthalate, polyisopentyl terephthalate, and polyneopentyl terephthalate. The alkylene units may be straight or branched chains.

The preferred polyalkylene terephthalates may contain, in addition to terephthalic acid groups, up to 20 mol % of groups from other aromatic dicarboxylic acids with 8 to 14 carbon atoms or aliphatic dicarboxylic acids with 4 to 12 carbon atoms, such as groups from phthalic acid, isophthalic acid, naphthalene-2,6-dicarboxylic acid, 4,4′-di-phenyl-dicarboxylic acid, succinic, adipic, sebacic, azelaic acids or cyclohexanediacetic acid. The preferred polyalkylene terephthalates may contain, in addition to ethylene glycol or butanediol-1,4-groups, up to 20 mol % of other aliphatic diols with 3 to 12 carbon atoms or cylcoaliphatic diols with 6 to 21 carbon atoms, e.g., groups from propanediol-1,3,2-ethylpropanediol-1,3, neopentyl glycol, pentanediol-1,5, hexanediol-1,6, cyclohexane-dimethanol-1,4,3-methylpentanediol-2,4,2-methyl-pentanediol-2,4,2,2,4-trimethylpentanediol-1,3, and -1,6,2-ethylhexanediol-1,3,2,2-diethylpropanediol-1,3, hexanediol-2,5,1,4-di-(13-hydroxyethoxy)-benzene, 2,2-bis-(4-hydroxycyclohexyl)-propane, 2,4-dihydroxy-1,1,3,3-tetra-methyl-cyclobutane, 2,2-bis-(3-β-hydroxyethoxyphenyl)-propane and 2,2-bis-(4-hydroxypropoxyphenyl)-propane (see, DE-OS 24 07 674, 24 07 776, 27 15 932).

The polyalkylene terephthalates may be branched by incorporating relatively small amounts of 3- or 4-hydric alcohols or 3- or 4-basic carboxylic acids, such as are described, for example, in DE-OS 19 00 270 and U.S. Pat. No. 3,692,744. Examples of preferred branching agents comprise trimesic acid, trimellitic acid, trimethylol-ethane and -propane and pentaerythritol. Preferably no more than 1 mol % of branching agent, with respect to the acid component, is used.

Polyalkylene terephthalates prepared solely from terephthalic acid and its reactive derivatives (e.g., its diallyl esters) and ethylene glycol and/or butanediol-1,4 (polyethyleneterephthalate and polybutyleneterephthalate) and mixtures of these polyalkylene terephthalates are particularly preferred. Suitable polyalkylene terephthalates are disclosed in U.S. Pat. Nos. 4,267,096; 4,786,692; 4,352,907; 4,391,954; 4,125,571; 4,125,572; 4,188,314; and 5,407,994.

The at least one amorphous thermoplastic is present in an amount ranging from 90% to 30% of the composition useful in the present invention, more preferably from 80% to 40% and most preferably from 70% to 50%. The at least one amorphous thermoplastic may be present in the composition of the present invention in an amount ranging between any combination of these values, inclusive of the recited values.

Expanded graphite and methods of its production are known to those skilled in the art. Expanded graphite may present in an amount ranging from 10 wt. % to 70 wt. % of the composition useful the present invention, more preferably from 20 wt. % to 60 wt. % and most preferably from 30 wt. % to 50 wt. %. The expanded graphite may be present in an amount ranging between any combinations of these values, inclusive of the recited values. It is preferred that at least 90% of the particles of the expanded graphite should have a particle size of at least 200 microns. There are also highly thermally conductive expanded graphite compounds commercially available, which have a lower particles size, e.g., where 90% of the particles have a maximum particle size of 100 microns, which may alternatively be used.

The thermally conductive polycarbonate composition may further include effective amounts of any of the additives known for their function in the context of thermoplastic molding compositions. These include any one or more of lubricants, mold release agents, for example pentaerythritol tetrastearate, nucleating agents, antistatic agents, other antioxidants, thermal stabilizers, light stabilizers, hydrolytic stabilizers, impact modifiers, fillers and reinforcing agents, colorants, or pigments, as well as further flame retarding agents, other drip suppressants or flame retarding synergists. The additives may be used in effective amounts, preferably of from 0.01 to a total of 30 wt. % relative to the total weight of the polycarbonate component.

The thermally conductive polycarbonate composition may be produced by conventional procedures using conventional equipment. It may be used to produce moldings of any kind by thermoplastic processes such as injection molding, extrusion, and blow molding methods.

As known to those in the art, a wide variety of different molded thermoplastic parts may be produced by the reaction injection molding (“RIM”) process. This process involves filling a closed mold with highly reactive liquid starting components within a very short time, generally by using high output, high pressure dosing apparatus after the components have been mixed. The RIM process involves the intimate mixing of a components of the thermoplastic composition, followed by the injection of this mixture into a mold for subsequent rapid curing. For a thermoplastic such as polyurethane, such as may be used to form housings for the insert-molded electronic modules, the components may include a polyisocyanate components and an isocyanate-reactive component. For example, the polyisocyanate component may preferably be based on a liquid polyisocyanate, and the isocyanate-reactive component may contain a high molecular weight isocyanate-reactive component, preferably a polyol and/or an amine polyether, and may contain a chain extender containing amino and/or hydroxyl groups.

A variety of patents describe various RIM processes, which are suitable in the practice of the present invention including, U.S. Pat. Nos.4,218,543; 4,433,067; 4,444,910; 4,530,941; 4,774,263; 4,774,264; 4,929,697; 5,003,027; 5,350,778; 5,563,232; 5,585,452; and 5,686,042. Polyurethanes useful in RIM processes are preferably produced by the reaction of at least one relatively high molecular weight hydroxyl-containing polyol, at least one chain extender; and at least one polyisocyanate, polyisothiocyanate or mixtures thereof. Suitable polyurethanes are disclosed, for example, in U.S. Pat. No. 10,156,352.

Other materials which can be included in the reaction mixture included any of the materials generally used in the RIM art. Reinforcing fillers, which allow reduced contraction of the molded product upon cooling, as well as adjustment of tensile modulus and flex modulus, can also be used and are well known in the art. Suitable inorganic fillers include glass in the form of fibers or flakes, mica, wollastonite, carbon black, talc, calcium carbonate, and carbon fibers. Organic fillers, although less preferred, are also suitable.

Other additives which may be used in the present invention include catalysts, especially tin (II) salts of carboxylic adds, dialkyltin salts of carboxylic acids, dialkyltin mercaptides, dialkyltin dithioesters, and tertiary amines. Preferred among these catalysts are dibutyltin dilaurate and 1,4-diazabicyclo[2,2,21]octane (triethylene diamine), especially mixtures of these catalysts. The catalysts are preferably used in amounts of 0.01 to 10% (preferably 0.05 to 2%), based on the weight of the high molecular weight component.

It is also possible to use surface-active additives such as emulsifiers and foam stabilizers. Examples include siloxanes, N-stearyl-N′,N′-bis-hydroxyethyl urea, oleyl polyoxyethylene amide, stearyl diethanol amide, isostearyl diethanolamide, polyoxyethylene glycol monoleate, a pentaerythritol/adipic acid/oleic acid ester, a hydroxyethyl imidazole derivative of oleic acid, N-stearyl propylene diamine, and the sodium salts of castor oil sulfonates or of fatty acids. Alkali metal or ammonium salts of sulfonic acid, such as dodecylbenzenesulfonic add or dinaphthylmethanesulfonic acid, and fatty acids may also be used as surface-active additives. Particularly suitable surface-active compounds include polyether siloxanes of the type generally known for use in the polyurethane art, such as water-soluble polyether siloxanes. The structure of these siloxanes is such that a copolymer of ethylene oxide and propylene oxide is attached to a polydimethylsiloxane functionality. Methods of manufacturing preferred siloxanes are described in U.S. Pat. No. 4,906,721.

It is also possible to use mold release agents, which are compounds that are added to the reactive components of the isocyanate addition reaction, usually the isocyanate-reactive component, to assist in the removal of a polyurethane product from a mold. Suitable mold release agents for the present invention include those based at least in part on fatty acid esters (e.g., U.S. Pat. Nos. 3,726,952, 3,925,527, 4,058,492, 4,098,731, 4,201,847, 4,254,228, 4,868,224, and 4,954,537 and British Patent 1,365,215); metal and/or amine salts of carboxylic acids, amido carboxylic acids, phosphorus-containing acids, or boron-containing acids (e.g., U.S. Pat. Nos. 4,519,965, 4,581,386, 4,585,803, 4,876,019, 4,895,879, and 5,135,962); polysiloxanes (e.g., U.S. Pat. No. 4,504,313); amidines (e.g., U.S. Pat. Nos. 4,764,540, 4,789,688, and 4,847,307); resins prepared by the reaction of isocyanate prepolymers and a polyamine-polyimine component (e.g., U.S. Pat. No. 5,198,508); neutralized esters prepared from certain amine-started tetrahydroxy compounds described in U.S. Pat. No. 5,208,268; and aliphatic polyalkylene and polyalkadienes. Preferred mold release agents contain zinc stearate.

In addition to the reinforcement fillers, catalysts, surface-active agents, and mold release agents mentioned above, other additives, which may be used in the molding compositions of the present invention, include known fillers of other types, blowing agents, cell regulators, flame retarding agents, plasticizers, and dyes of the types generally known in the art.

The compositions according to the present invention are suited for processing by the RIM process. In general, in the RIM process, two separate streams are intimately mixed and subsequently injected into a suitable mold, although it is possible to use more than two streams. In the known RIM process used for conducting the process according to the present invention, the components may be mixed simultaneously, or the non-reactive components may be pre-mixed and then mixed with the reactive components. A starting temperature of from 10° C. to 70° C., preferably from 30° C. to 50° C. is chosen for the mixture introduced into the mold. The temperature of the mold itself is preferably from 40° C. to 100° C., more preferably from 50° C. to 70° C. After completion of the reaction and molding process, the resultant product is removed from the mold.

The electronics/electrical component may be selected from among printed circuit boards (PCBs), light emitting diodes (LEDs), resistors, constant current drivers, drivers/controllers, capacitors, microprocessors, integrated circuits, photocells, piezo-transducers, inductors, and proximity switches.

Exemplary printed circuit boards include metal core printed circuit boards, as well as printed circuit boards formed of laminates and dielectric materials, such as polytetrafluoroethylene (Teflon), FR-2 (phenolic cotton paper), FR-3 (cotton paper and epoxy), FR-4 (woven glass and epoxy), FR-5 (woven glass and epoxy), FR-6 (matte glass and polyester), G-10 (woven glass and epoxy), CEM-1 (cotton paper and epoxy), CEM-2 (cotton paper and epoxy), CEM-3 (non-woven glass and epoxy), CEM-4 (woven glass and epoxy), and CEM-5 (woven glass and polyester). Preferable printed circuit boards include metal core boards and FR-4 (woven glass and epoxy) boards.

The openings in the electronic/electrical component may be standard openings, such as attachment openings (e.g., screw holes), through holes, vias (e.g., through-hole vias, blind vias, buried vias, microvias, and stacked microvias), or any combination thereof. The openings may further include holes made specifically for entry of the thermally conductive thermoplastic polymer composition to form the in-mold electronics assembly of the present invention.

In some embodiments, in-mold electronics assembly may include heat dissipation elements such as fins. The fins may extend from a base portion of the in-mold electronics assembly and may provide additional air flow therethrough to aid in heat dissipation from the in-mold electronics assembly. The fins may be positioned on a side of the in-mold electronics assembly opposite from the electronic/electrical component.

### EXAMPLES

The non-limiting and non-exhaustive examples that follow are intended to further describe various non-limiting and non-exhaustive embodiments without restricting the scope of the embodiments described in this specification. All quantities given in “parts” and “percents” are understood to be by weight, unless otherwise indicated.

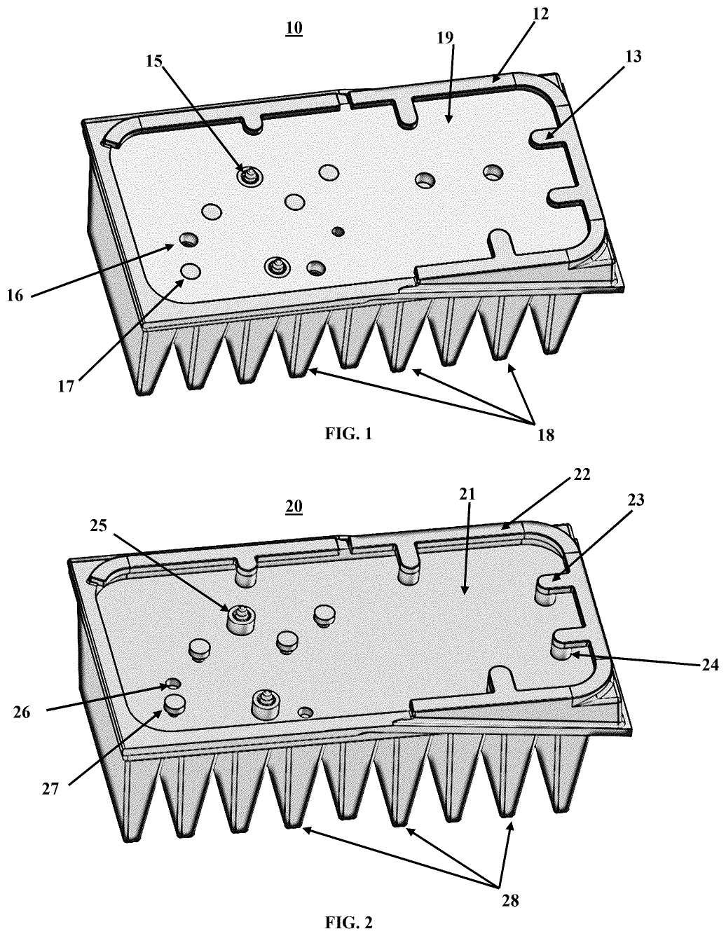

As shown in FIG. 1, an in-mold electronics assembly 10, comprising a thermally conductive thermoplastic polymer composition, surrounds a board component 19 such as a printed circuit board base or a metal insert. In those embodiments where the board component 19 comprises a printed circuit board base, it is preferably made of FR-4 (woven glass and epoxy). In those embodiments where the board component 19 is a metal insert, it is preferably made of aluminum or copper. Tab 13 and insert anchor 12 help to secure board component 19 in insert pocket 11 (shown in FIG. 2 as 21) of in-mold electronics assembly 10. Opening 16, in the board component, such as a screw hole with screw 15 protruding therefrom, and a flow through button 17 are also shown. The openings 16 and flow through buttons permit the attachment of electronics to the board and allow the thermally conductive thermoplastic polymer composition to flow through and interlock the board and attached electronics. A plurality of fins 18, comprising the thermally conductive thermoplastic polymer composition, may be preferably molded into or onto the base of the in-mold electronics assembly 10 to assist with heat dissipation.

FIG. 2 depicts a perspective view of the in-mold electronics assembly 20 of the invention, comprising a thermally conductive thermoplastic polymer composition, with the board component removed to better show insert pocket 21. Tab 23 is connected to insert anchor 22 which contacts insert pocket 21 through post 24. Opening 26, such as a screw hole with screw 25 protruding therefrom, and flow through button 27 are also shown. A plurality of fins 28, comprising the thermally conductive thermoplastic polymer composition, may preferably be molded into, or attached to the base of the in-mold electronics assembly.

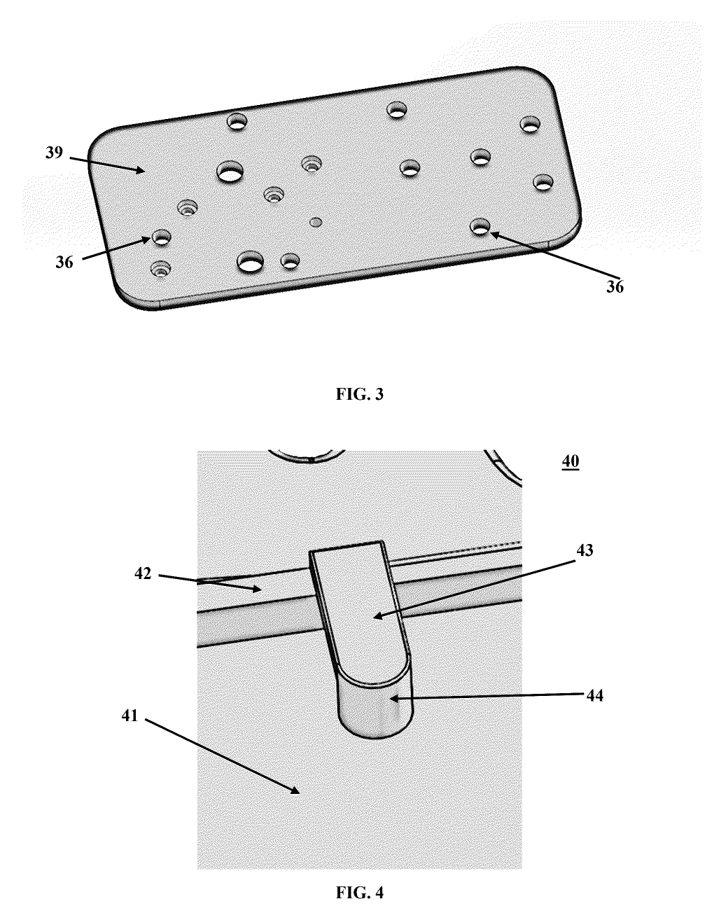

FIG. 3 illustrates board component 39 which is detached from the in-mold electronics assembly of the invention. A plurality of openings 36 through board component 39 are shown. This plurality of openings allows the thermally conductive thermoplastic polymer composition to interlock the board component the in-mold electronics assembly.

FIG. 4 is an enlarged view of a portion of FIG. 2 showing a tab for securing the board component to the in-mold electronics assembly of the invention. As shown in FIG. 4, tab 43 secures the board component (not shown) to insert pocket 41 of the in-mold electronics assembly. Tab 43 presses against post 44 which sits atop the board component in insert pocket 41 of the in-mold electronics assembly 40. Also shown is a portion of insert anchor 42 where tab 43 attaches to the insert anchor 42.

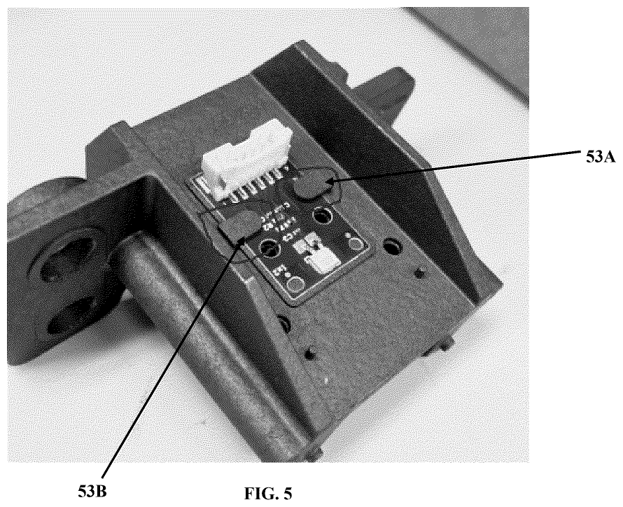

FIG. 5 is a photograph of a part showing the “collar system” of the invention securing an in-mold electronics assembly of the invention to a molded part with tabs 53A and 53B pressing down on the in-mold electronics assembly.

This specification has been written with reference to various non-limiting and non-exhaustive embodiments. However, it will be recognized by persons having ordinary skill in the art that various substitutions, modifications, or combinations of any of the disclosed embodiments (or portions thereof) may be made within the scope of this specification. Thus, it is contemplated and understood that this specification supports additional embodiments not expressly set forth herein. Such embodiments may be obtained, for example, by combining, modifying, or reorganizing any of the disclosed steps, components, elements, features, aspects, characteristics, limitations, and the like, of the various non-limiting embodiments described in this specification. In this manner, Applicant reserves the right to amend the claims during prosecution to add features as variously described in this specification, and such amendments comply with the requirements of 35 U.S.C. § 112(a), and 35 U.S.C. § 132(a).

Various aspects of the subject matter described herein are set out in the following numbered clauses:

In a first aspect, the present invention is directed to a process of securing a board component in an in-mold electronics assembly, the process comprising: inserting the board component into a mold; injecting a thermally conductive thermoplastic polymer composition into the mold and into a flow-through collar to flow over the board component which lies within an insert pocket in the in-mold electronics assembly; cooling the thermally conductive thermoplastic polymer composition securing the board component and forming the in-mold electronics assembly; and removing the in-mold electronics assembly from the mold, wherein the board component optionally includes one or more attachment openings, through holes, through-hole vias, blind vias, buried vias, microvias, stacked microvias, and any combination thereof allowing the thermally conductive thermoplastic polymer composition to flow therethrough.

In a second aspect, the present invention is directed to the process according to the previous paragraph, wherein the board component is further secured with a tab connected to an insert anchor of the in-mold electronics assembly, and wherein the insert anchor contacts the insert pocket through a post.

In a third aspect, the present invention is directed to a process of securing a board component in an in-mold electronics assembly, the process comprising: inserting the board component into a mold; injecting a thermally conductive thermoplastic polymer composition into the mold and flowing the thermally conductive thermoplastic polymer composition, a) over the board component lying within an insert pocket in the in-mold electronics assembly, forming an insert anchor adjacent to the board component, and b) over a post protruding perpendicularly from the insert pocket, forming a tab; cooling the thermally conductive thermoplastic polymer composition, securing the board component, and forming the in-mold electronics assembly; and removing the in-mold electronics assembly from the mold.

In a fourth aspect, the present invention is directed to the process according to any one of the previous three paragraphs, wherein the board component is selected from the group consisting of a printed circuit board, and a metal insert.

In a fifth aspect, the present invention is directed to the process according to any one of the previous four paragraphs, wherein the thermally conductive thermoplastic polymer composition comprises a polymer selected from the group consisting of polycarbonate, polymethylmethacrylate (PMMA) and polystyrene.

In a sixth aspect, the present invention is directed to the process according to any one of the previous five paragraphs, wherein the thermally conductive thermoplastic polymer composition comprises a blend selected from the group consisting of polycarbonate and polyethylene terephthalate, polycarbonate and polybutylene terephthalate, polycarbonate and polyphenylene sulfide, and polycarbonate and liquid crystalline polymers.

In a seventh aspect, the present invention is directed to the process according to any one of the previous six paragraphs, wherein the thermally conductive thermoplastic polymer composition comprises expanded graphite particles in an amount of from 10 wt. % to 70 wt. % of the composition, more preferably from 20 wt. % to 60 wt. % of the composition, most preferably from 30 wt. % to 50 wt. % of the composition.

In an eighth aspect, the present invention is directed to the process according to the previous paragraph, wherein at least 90% of the expanded graphite particles have a particle size of at least 200 microns.

In a ninth aspect, the present invention is directed to an in-mold electronics assembly made according to the process of any one of the previous eight paragraphs.

In a tenth aspect, the present invention is directed to an in-mold electronics assembly comprising: a board component; a flow-through collar; and a thermally conductive thermoplastic polymer composition, wherein the thermally conductive thermoplastic polymer composition is injected into a mold and into the flow-through collar, wherein the thermally conductive thermoplastic polymer composition flows over the board component securing the board component to the in-mold electronics assembly, and wherein the board component optionally includes one or more attachment openings, through holes, through-hole vias, blind vias, buried vias, microvias, stacked microvias, and any combination thereof allowing the thermally conductive thermoplastic polymer composition to flow therethrough.

In an eleventh aspect, the present invention is directed to the in-mold electronics assembly according to the previous paragraph, wherein the board component is selected from the group consisting of a printed circuit board, and a metal insert.

In a twelfth aspect, the present invention is directed to the in-mold electronics assembly according to one of the previous two paragraphs, wherein the thermally conductive thermoplastic polymer composition comprises a polymer selected from the group consisting of polycarbonate, polymethylmethacrylate (PMMA) and polystyrene.

In a thirteenth aspect, the present invention is directed to the in-mold electronics assembly according to any one of the previous three paragraphs, wherein the thermally conductive thermoplastic polymer composition comprises a blend selected from the group consisting of polycarbonate and polyethylene terephthalate, polycarbonate and polybutylene terephthalate, polycarbonate and polyphenylene sulfide, and polycarbonate and liquid crystalline polymers.

In a fourteenth aspect, the present invention is directed to the in-mold electronics assembly according to any one of the previous four paragraphs, wherein the thermally conductive thermoplastic polymer composition comprises expanded graphite particles in an amount of from 10 wt. % to 70 wt. % of the composition, more preferably from 20 wt. % to 60 wt. % of the composition, most preferably from 30 wt. % to 50 wt. % of the composition.

In a fifteenth aspect, the present invention is directed to the in-mold electronics assembly according to the previous paragraph, wherein at least 90% of the expanded graphite particles have a particle size of at least 200 microns.

1. A process of securing a board component in an in-mold electronics assembly, the process comprising:
inserting the board component into a mold;
injecting a thermally conductive thermoplastic polymer composition into the mold and into a flow-through collar to flow over the board component which lies within an insert pocket in the in-mold electronics assembly;
cooling the thermally conductive thermoplastic polymer composition securing the board component and forming the in-mold electronics assembly; and
removing the in-mold electronics assembly from the mold,
wherein the board component optionally includes one or more attachment openings, through holes, through-hole vias, blind vias, buried vias, microvias, stacked microvias, and any combination thereof allowing the thermally conductive thermoplastic polymer composition to flow therethrough.

2. The process according to claim 1, wherein the board component is further secured with a tab connected to an insert anchor of the in-mold electronics assembly, and wherein the insert anchor contacts the insert pocket through a post.

3. A process of securing a board component in an in-mold electronics assembly, the process comprising:
inserting the board component into a mold;
injecting a thermally conductive thermoplastic polymer composition into the mold and flowing the thermally conductive thermoplastic polymer composition,
a) over the board component lying within an insert pocket in the in-mold electronics assembly, forming an insert anchor adjacent to the board component, and
b) over a post protruding perpendicularly from the insert pocket, forming a tab;
cooling the thermally conductive thermoplastic polymer composition, securing the board component, and forming the in-mold electronics assembly; and
removing the in-mold electronics assembly from the mold.

4. The process according to claim 1, wherein the board component is selected from the group consisting of a printed circuit board, and a metal insert.

5. The process according to claim 1, wherein the thermally conductive thermoplastic polymer composition comprises a polymer selected from the group consisting of polycarbonate, polymethylmethacrylate (PMMA) and polystyrene.

6. The process according to claim 1, wherein the thermally conductive thermoplastic polymer composition comprises a blend selected from the group consisting of polycarbonate and polyethylene terephthalate, polycarbonate and polybutylene terephthalate, polycarbonate and polyphenylene sulfide, and polycarbonate and liquid crystalline polymers.

7. The process according to claim 1, wherein the thermally conductive thermoplastic polymer composition comprises expanded graphite particles in an amount of from 10 wt. % to 70 wt. % of the composition, more preferably from 20 wt % to 60 wt % of the composition, most preferably from 30 wt % to 50 wt % of the composition.

8. The process according to claim 7, wherein at least 90% of the expanded graphite particles have a particle size of at least 200 microns.

9. The in-mold electronics assembly made according to the process of claim 1.

10. An in-mold electronics assembly comprising:
a board component;
a flow-through collar; and
a thermally conductive thermoplastic polymer composition,
wherein the thermally conductive thermoplastic polymer composition is injected into a mold and into the flow-through collar,
wherein the thermally conductive thermoplastic polymer composition flows over the board component securing the board component to the in-mold electronics assembly, and
wherein the board component optionally includes one or more attachment openings, through holes, through-hole vias, blind vias, buried vias, microvias, stacked microvias, and any combination thereof allowing the thermally conductive thermoplastic polymer composition to flow therethrough.

11. The in-mold electronics assembly according to claim 10, wherein the board component is selected from the group consisting of a printed circuit board, and a metal insert.

12. The in-mold electronics assembly according to claim 10, wherein the thermally conductive thermoplastic polymer composition comprises a polymer selected from the group consisting of polycarbonate, polymethylmethacrylate (PMMA) and polystyrene.

13. The in-mold electronics assembly according to claim 10, wherein the thermally conductive thermoplastic polymer composition comprises a blend selected from the group consisting of polycarbonate and polyethylene terephthalate, polycarbonate and polybutylene terephthalate, polycarbonate and polyphenylene sulfide, and polycarbonate and liquid crystalline polymers.

14. The in-mold electronics assembly according to claim 10, wherein the thermally conductive thermoplastic polymer composition comprises expanded graphite particles in an amount of from 10 wt. % to 70 wt. % of the composition, more preferably from 20 wt. % to 60 wt. % of the composition, most preferably from 30 wt. % to 50 wt. % of the composition.

15. The in-mold electronics assembly according to claim 14, wherein at least 90% of the expanded graphite particles have a particle size of at least 200 microns.
